(19) United States
(12) Patent Application Publication
(10) Pub. No.: US 2026/0164828 A1
(43) Pub. Date: Jun. 11, 2026

(54) IMAGE SENSOR DEVICE AND METHOD FOR FABRICATING THE SAME

(71) Applicant: TAIWAN SEMICONDUCTOR MANUFACTURING COMPANY, LTD., Hsinchu (TW)

(72) Inventors: Wei-Lin CHANG, Changhua City (TW); Wen-Lan YEH, New Taipei City (TW); Chi-Jan CHO, Hsinchu City (TW)

(73) Assignee: TAIWAN SEMICONDUCTOR MANUFACTURING COMPANY, LTD., Hsinchu (TW)

(21) Appl. No.: 18/970,236

(22) Filed: Dec. 5, 2024

(51) Int. Cl. H10F 39/00; H10F 39/18

(52) U.S. Cl. CPC H10F 39/807; H10F 39/014; H10F 39/182; H10F 39/811

(57) ABSTRACT

A method for fabricating an image sensor device is provided. The method includes forming a plurality of photosensitive regions in a semiconductor substrate through a frontside of the semiconductor substrate; etching a first trench and a second trench in a backside of the semiconductor substrate after forming the photosensitive regions, wherein the first trench is deeper than the second trench, and a first line width of the first trench is less than a second line width of the second trench in a first top view; and forming a first isolation feature in the first trench and a second isolation feature in the second trench.

### BACKGROUND

Integrated circuits (IC) with image sensors are used in a wide range of modern day electronic devices. In recent years, complementary metal-oxide semiconductor (CMOS) image sensors have begun to see widespread use, largely replacing charge-coupled devices (CCD) image sensors. Compared to CCD image sensors, CMOS image sensors are increasingly favored due to low power consumption, a small size, fast data processing, a direct output of data, and low manufacturing cost. Some types of CMOS image sensors include frontside illuminated (FSI) image sensors and backside illuminated (BSI) image sensors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-12 illustrate a method of fabricating an image sensor device according to various embodiments of the present disclosure.

FIG. 13 is a top view of a patterned photoresist layer according to various embodiments of the present disclosure.

FIG. 14A is a cross-sectional view of an image sensor device according to various embodiments of the present disclosure.

FIG. 14B is a top view of the image sensor device of FIG. 14A.

FIG. 14C is a plan view of the image sensor device of FIG. 14A.

FIG. 15A is a cross-sectional view of an image sensor device according to various embodiments of the present disclosure.

FIG. 15B is a top view of the image sensor device of FIG. 15A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present embodiments, a method for forming a trench with vertical sidewalls is provided. The trench may have a high aspect ratio. The trench may be filled with dielectric materials, thereby forming an isolation structure, such as a deep trench isolation (DTI) structure or a shallow trench isolation (STI) for an image sensor integrated chip. Although the isolation structure in the present embodiments are illustrated within a back-illuminated CMOS (BSI) image sensor, it will be appreciated that the disclosed isolation structure may also be used with frontside image (FSI) image sensors. Furthermore, the method for forming the trench with a high aspect ratio and forming the isolation structure in the trench may be used in other process, not limited the process of fabricating an image sensor.

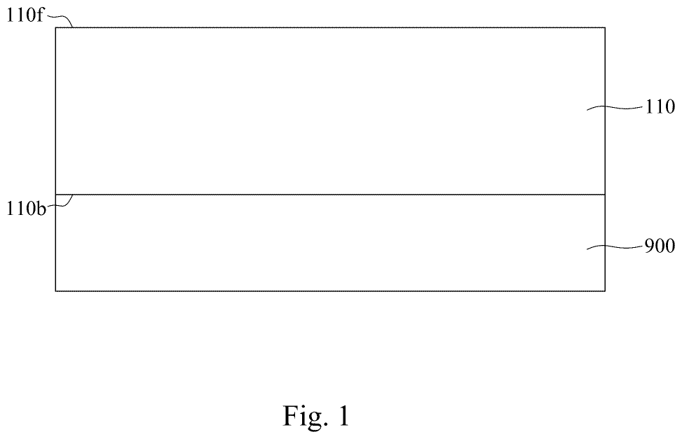

FIGS. 1-11 illustrate a method of fabricating an image sensor according to various embodiments of the present disclosure. The substrate 110 may be any type of semiconductor body (e.g., silicon, SiGe, semiconductor-on-insulator (SOI), etc.), as well as any other type of semiconductor and/or epitaxial layers, associated therewith. For example, in some embodiments, the substrate 110 may include a base substrate and an epitaxial layer. In some embodiments, the substrate 110 may include a silicon substrate. In some embodiments, the substrate 110 may be thinned by etching and/or mechanical grinding a frontside 110f of the substrate 110 after bonding a backside 110b of the substrate 110 to a support substrate 900. Thinning the substrate 110 allows for radiation to pass more easily to a photosensitive region subsequently formed within the substrate 110.

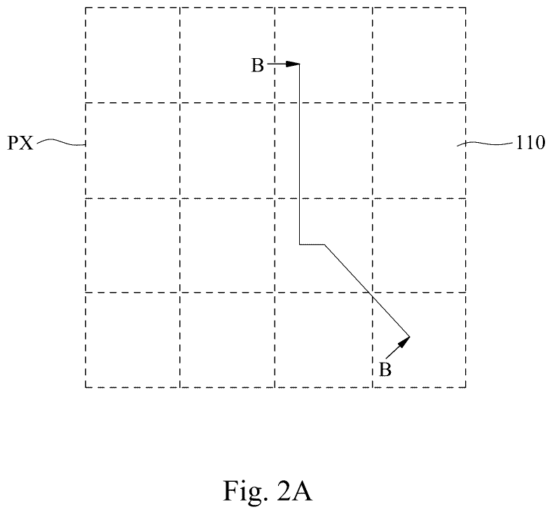

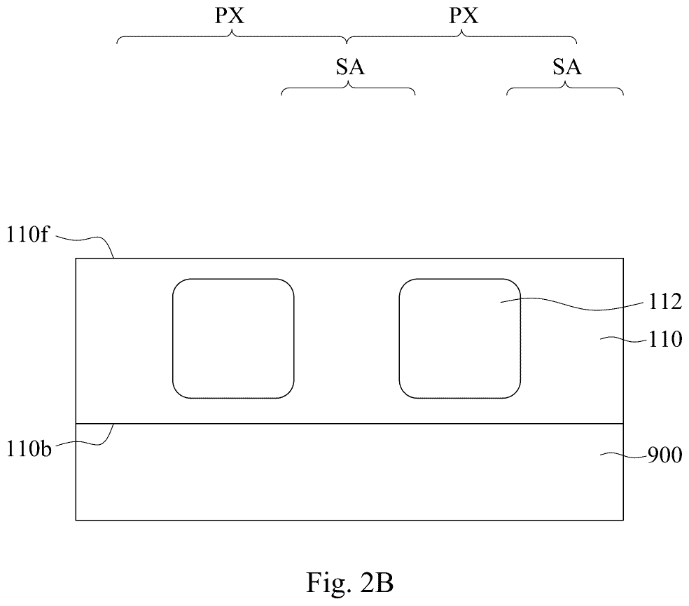

Reference is made to FIGS. 2A and 2B. FIG. 2B is a cross-sectional view taken along line B-B of FIG. 2A. Plural photosensitive regions 112 are formed within pixel regions PX of the substrate 110, respectively. In some embodiments, the photosensitive region 112 may include photodiodes formed by implanting or diffusing one or more dopant species into a frontside 110f of the substrate 110. The photosensitive regions 112 are doped with a doping polarity opposite from that of the substrate 110. For example, the substrate 110 is a p-type substrate, and the photosensitive regions 112 are regions doped with n-type dopants, such as phosphorus, antimony, and arsenic. The photosensitive regions 112 are formed adjacent to or near the frontside 110f of the substrate 110. The photosensitive regions 112 are operable to sense incident radiation that enters the pixel region PX from the backside 110b of the substrate 110. The incident radiation may be visual light. Alternatively, the incident radiation may be infrared (IR), far infrared (FIR), ultraviolet (UV), X-ray, microwave, other suitable types of radiation, or a combination thereof.

Plural photosensitive regions 112 are formed within pixel regions PX of the substrate 110, respectively. In some embodiments, the photosensitive region 112 may include photodiodes formed by implanting or diffusing one or more dopant species into a frontside 110f of the substrate 110. For example, the photosensitive regions 112 are doped with a doping polarity opposite from that of the substrate 110. The photosensitive regions 112 are formed adjacent to or near the frontside 110f of the substrate 110. The photosensitive regions 112 are operable to sense incident radiation that enters the pixel region PX from the backside 110b of the substrate 110. The incident radiation may be visual light. Alternatively, the incident radiation may be infrared (IR), far infrared (FIR), ultraviolet (UV), X-ray, microwave, other suitable types of radiation, or a combination thereof. In some embodiments, the pixel regions PX are distributed as a two-dimensional array along directions X and Y, in which the direction X is substantially orthogonal to the direction Y. In some other embodiments, the pixel regions PX can be arranged in any suitable pattern, and not limited to the two-dimensional array along directions X and Y.

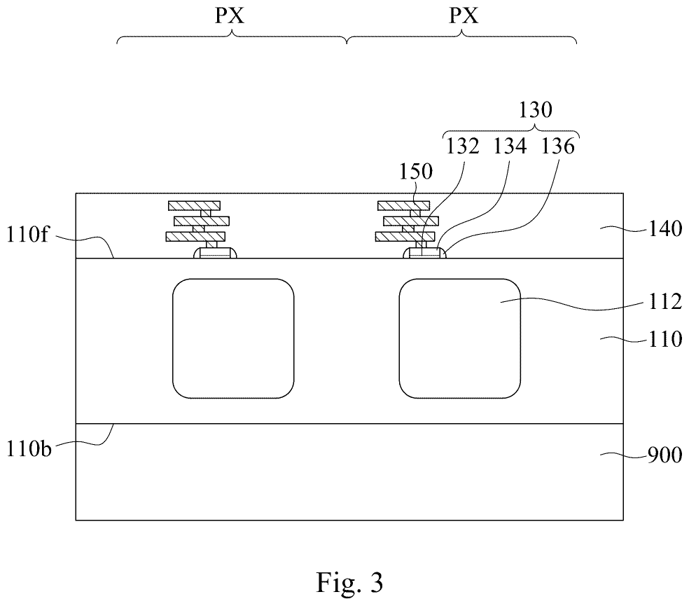

Reference is made to FIG. 3. One or more transistor gate structures 130 are formed along the frontside 110f of the substrate 110 within the pixel regions PX. In various embodiments, the one or more transistor gate structures 130 may correspond to a transfer transistor, a source-follower transistor, a row select transistor, and/or a reset transistor. In some embodiments, the one or more transistor gate structures 130 may be formed by depositing a gate dielectric film and a gate electrode film on the frontside 110f of the substrate 110. The gate dielectric film and the gate electrode film are subsequently patterned to form a gate dielectric layer 132 and a gate electrode 134. Sidewall spacers 136 may be formed on the outer sidewalls of the gate electrode 134. In some embodiments, the sidewall spacers 136 may be formed by depositing a spacer layer (e.g., a nitride, an oxide, etc.) onto the frontside 110f of the substrate 110 and selectively etching the spacer layer to form the sidewall spacers 136. In some embodiments, source/drain regions are formed, by ion implantation or epitaxially growth, on two opposing sides of each of the gate structures 130.

Plural conductive interconnect layers 150 are formed within a dielectric structure 140 formed along the frontside 110f of the substrate 110. The dielectric structure 140 includes plural stacked ILD layers, while the plural conductive interconnect layers 150 include alternating layers of conductive wires and vias. In some embodiments, one or more of the plural conductive interconnect layers 150 may be formed using a damascene process (e.g., a single damascene process or a dual damascene process). The damascene process is performed by forming an ILD layer over the frontside 110f of the substrate 110, etching the ILD layer to form a via hole and/or a metal trench, and filling the via hole and/or metal trench with a conductive material. In some embodiments, the ILD layer may be deposited by a physical vapor deposition technique (e.g., physical vapor deposition (PVD), chemical vapor deposition (CVD), plasma enhanced CVD (PE-CVD), atomic layer deposition (ALD), etc.) and the conductive material may be formed using a deposition process and/or a plating process (e.g., electroplating, electro-less plating, etc.). In various embodiments, the plural conductive interconnect layers 150 may include tungsten, copper, or aluminum copper, for example.

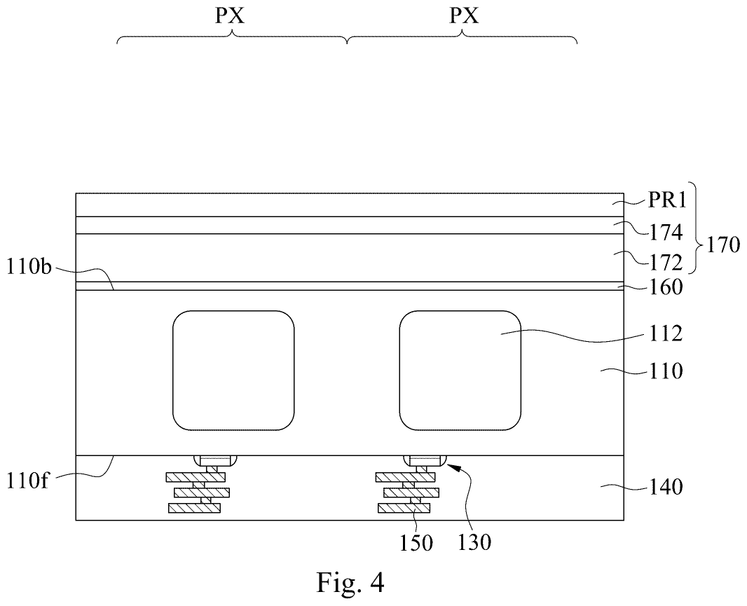

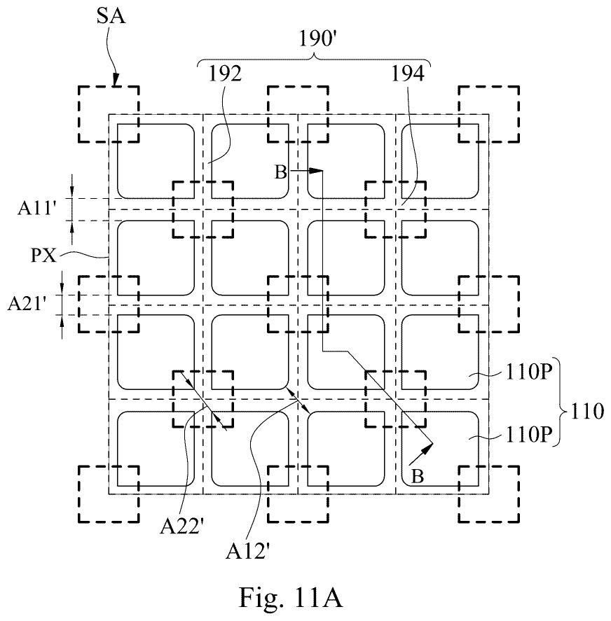

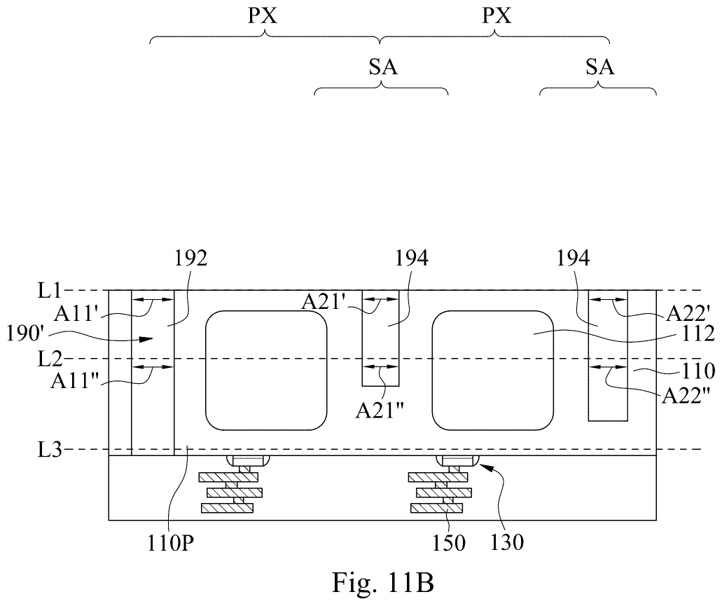

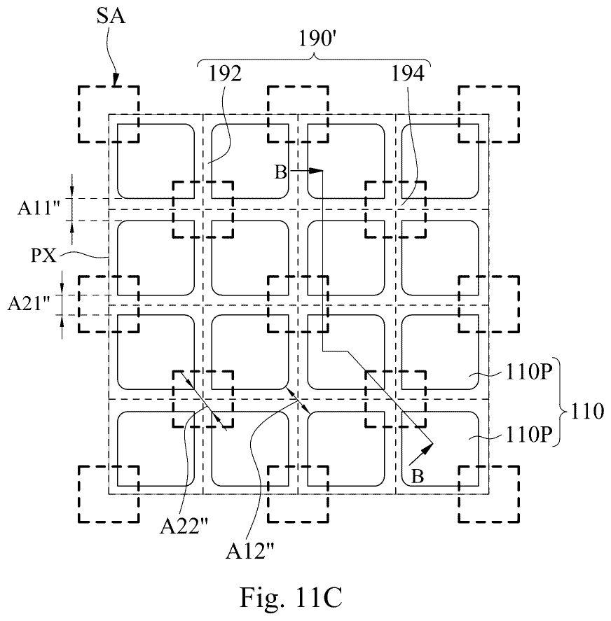

Subsequently, isolation features 192 and 194 (referring to FIGS. 11A-11D) are to be formed from the backside 110b of the substrate 110. The isolation features 192 and 194 (referring to FIGS. 11A-11D) may be formed by patterning the backside 110b of the substrate 110 to form plural trenches and filling the trenches with dielectric materials. In some cases where the trenches are formed with high aspect ratio, white pixel issues may occur due to tiny fence defect in the image sensor. In the present embodiments, FIGS. 4-11D shows a method for forming the trenches with improved profile, such that tiny fence defect can be lowered, thereby reducing the number of the white pixels.

Reference is made to FIG. 4. The substrate 110 is first flipped about the horizontal axis, and the support substrate 900 is removed. A mask layer 170 is formed on the backside 110b of the substrate 110. The mask layer 170 may include a bottom layer 172, a middle layer 174, and a photoresist layer PR1 stacked in a sequence. The bottom layer 172 may be an anti-reflective coating (ARC) layer, which reduces a reflection from underlying layers during photolithography. The bottom layer 172 may also act as an etch stop layer for etching the middle layer 172. The middle layer 174 may be deposited over the bottom layer 172. For example, the middle layer 174 may be a hard mask layer made of silicon nitride, silicon oxide, the like, or the combination thereof. The bottom layer 172, a middle layer 174 can include organic or inorganic materials. In some embodiments, the photoresist layer PR1 may be formed by coating a layer of photosensitive material (e.g., a positive or negative photoresist) on the middle layer 174. In some embodiments, prior to the formation of the mask layer 170, a surface layer 160 is formed on the backside 110b of the substrate 110. In some embodiments, the surface layer 160 may include silicon oxide formed by oxidation process.

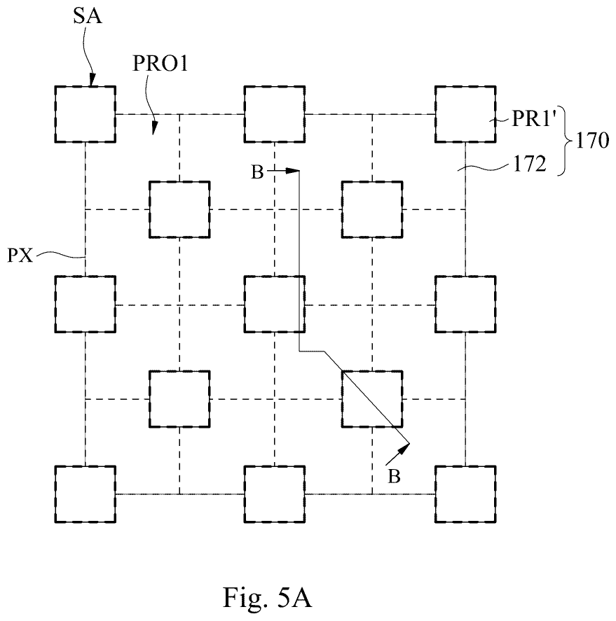

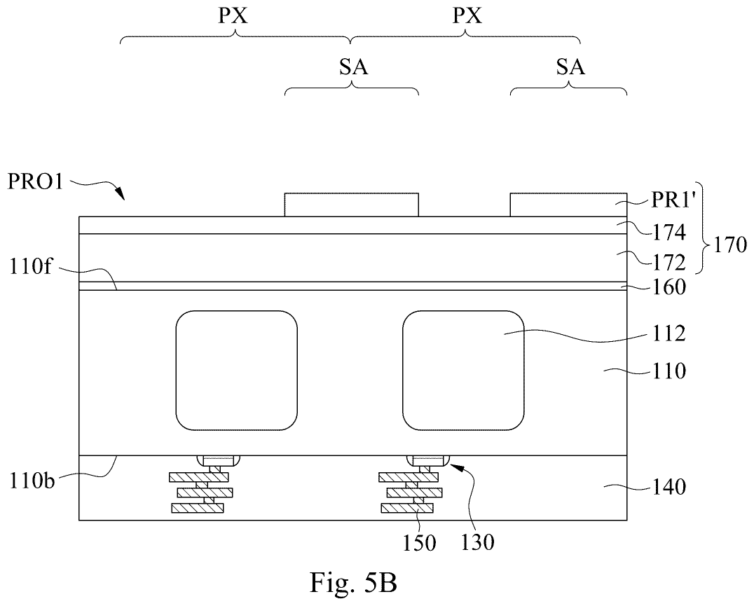

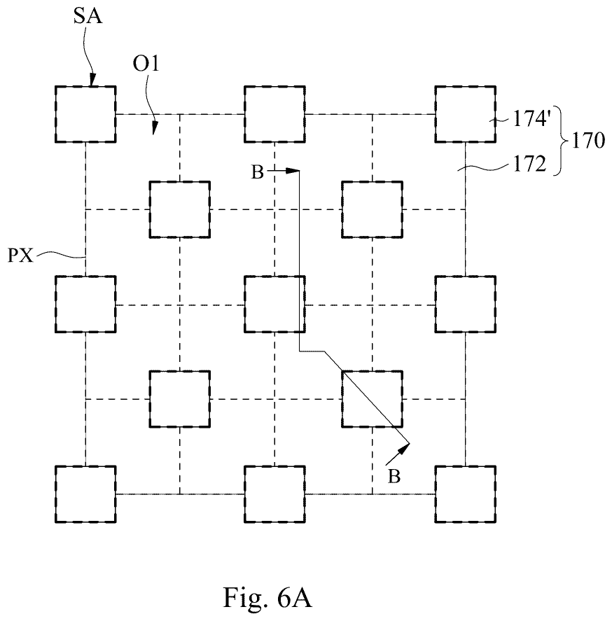

Reference is made to FIGS. 5A and 5B. FIG. 5B is a cross-sectional view taken along line B-B of FIG. 5A. In some embodiments, by exposing the photoresist layer PR1 (referring to FIG. 4) to light (e.g., ultraviolet light) using a reticle, the photoresist layer PR1 (referring to FIG. 4) is turned into a patterned photoresist layer PR1′ including openings PRO1. The layer of photosensitive material of the photoresist layer PR1 (referring to FIG. 4) is selectively exposed to electromagnetic radiation according to the reticle. The electromagnetic radiation modifies a solubility of exposed regions within the photosensitive material to define soluble regions. The photosensitive material is subsequently developed to define the openings PRO1 within the photosensitive material by removing the soluble regions. The intact portions of the patterned photoresist layer PR1′ may be aligned with non-through regions SA, where the non-through trench isolation features (e.g., the non-through isolation features 194 in FIGS. 11A-11D) are to be formed. In some embodiments, the non-through regions SA are respectively located at some intersections among four pixel regions PX. In the context, regions externals to the non-through regions SA may be referred to as through regions, where through trench isolation features (e.g., the isolation features 192 in FIGS. 11A-11D) are to be formed.

Stated differently, in FIGS. 4-5B, a lithography process (e.g., photolithography or e-beam lithography) is performed to form the patterned photoresist layer PR1′ having the openings PRO1. The lithography process includes photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof.

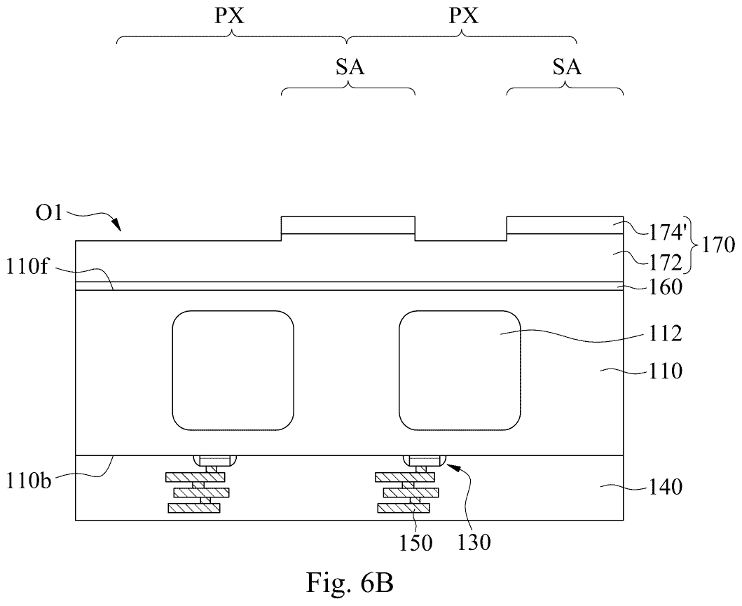

Reference is made to FIGS. 6A and 6B. FIG. 6B is a cross-sectional view taken along line B-B of FIG. 6A. The pattern of the photoresist layer PR1′ (e.g., the openings PRO1)(referring to FIGS. 5A and 5B) is then transferred to the middle layer 174 (referring to FIGS. 5A and 5B) using a suitable etching process. In some embodiments, the etching process may include dry etch (e.g., RIE), wet etch, other etch methods, and/or combinations thereof. To specific, the photoresist layer PR1′ is used as an etch mask to etch the underlying middle layer 174 (referring to FIGS. 5A and 5B). Accordingly, openings O1 are formed in the middle layer 174 (referring to FIGS. 5A and 5B). The middle layer 174 (referring to FIGS. 5A and 5B) are referred to as a patterned middle layer 174 after the formation of the openings O1. Like the pattern of the photoresist layer PR1′ (referring to FIGS. 5A and 5B), the intact portions of the patterned middle layer 174′ may be aligned with the non-through regions SA, where the non-through trench isolation features (e.g., the non-through isolation features 194 in FIGS. 11A-11D) are to be formed. The bottom layer 172 may serve as an etch stop layer during the etching process, and a portion of the bottom layer 172 exposed by the openings O1 may be consumed by the etching process. After the transferring/etching process, the photoresist layer PR1 may be removed by suitable stripping or ashing process.

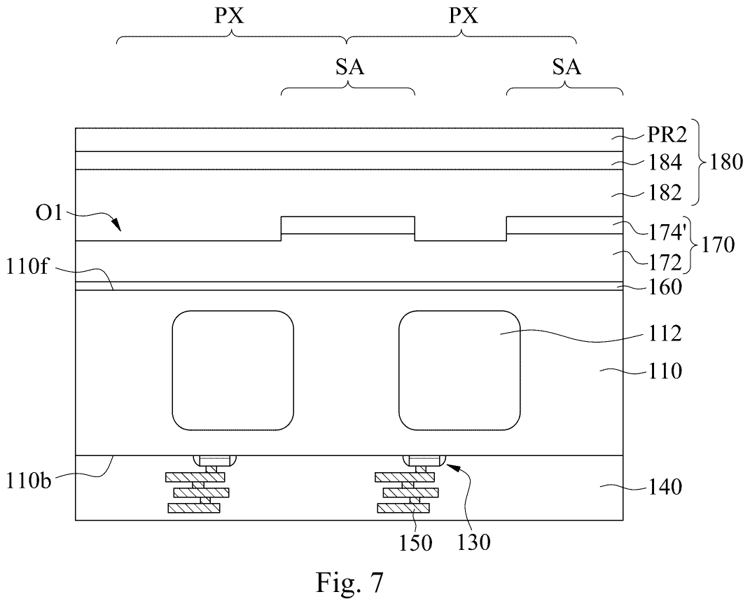

Reference is made to FIG. 7. A mask layer 180 is formed on the mask layer 170. The mask layer 180 may include a bottom layer 182, a middle layer 184, and a photoresist layer PR2 stacked in a sequence. The bottom layer 182 may be an anti-reflective coating (ARC) layer, which reduces a reflection from underlying layers during photolithography. The bottom layer 182 may also act as an etch stop layer for etching the middle layer 184. The middle layer 184 may be deposited over the bottom layer 182. For example, the middle layer 184 may be a hard mask layer made of silicon nitride, silicon oxide, the like, or the combination thereof. The bottom layer 182, a middle layer 184 can include organic or inorganic materials. In some embodiments, the photoresist layer PR2 may be formed by coating a layer of photosensitive material (e.g., a positive or negative photoresist) on the middle layer 184.

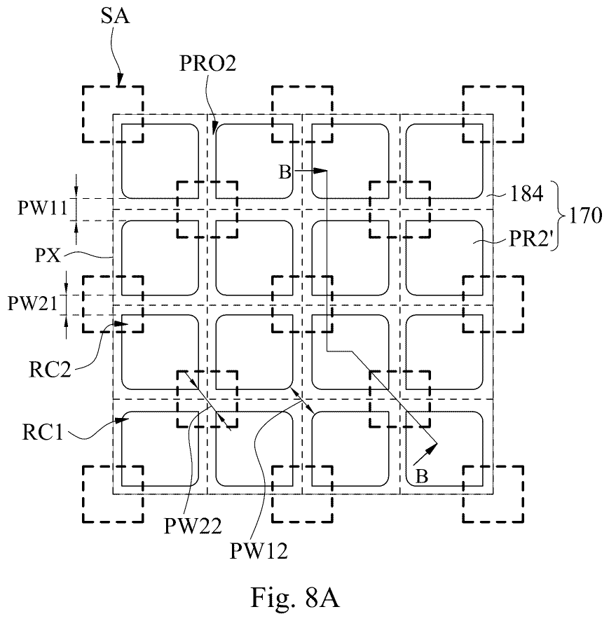

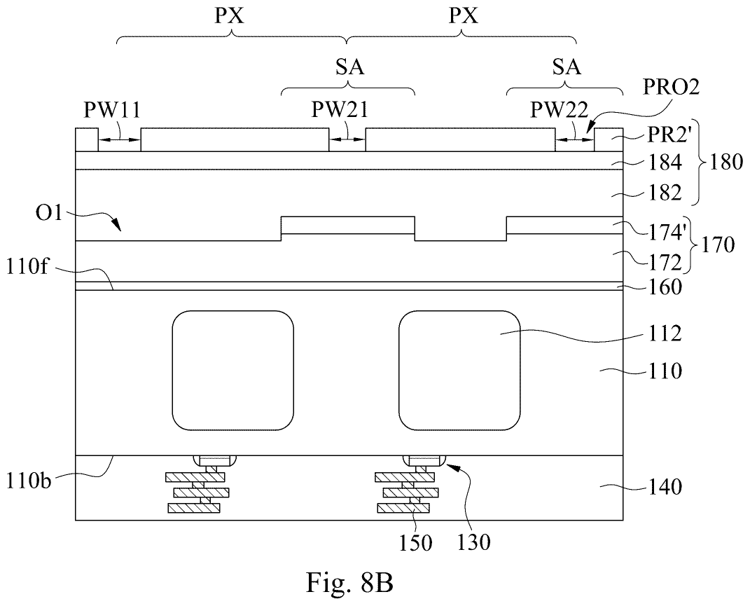

Reference is made to FIGS. 8A and 8B. In some embodiments, by exposing the photoresist layer PR2 (referring to FIG. 7) to light (e.g., ultraviolet light) using a reticle, the photoresist layer PR2 (referring to FIG. 7) is turned into a patterned photoresist layer PR2′ including openings PRO2. The layer of photosensitive material of the photoresist layer PR2 (referring to FIG. 7) is selectively exposed to electromagnetic radiation according to the reticle. The electromagnetic radiation modifies a solubility of exposed regions within the photosensitive material to define soluble regions. The photosensitive material is subsequently developed to define the openings PRO2 within the photosensitive material by removing the soluble regions. The openings PRO2 separates the pixel regions PX from each other.

In some embodiments, the patterned photoresist layer PR2′ has an asymmetric profile. For example, the line width PW21 of the openings PRO2 in the non-through region SA is greater than the line width PW11 of the openings PRO2 outside the non-through region SA. A difference between the line width PW21 and line width PW11 may be in a range from about 3 nm to about 20 nm. If the difference is less than 3 nanometers, the tiny fence detects may not be effectively reduced. If the difference is greater than 20 nanometers, it may be difficult to control the etch loading effect during trench etching process.

In some embodiments, for achieving the asymmetric profile, a ratio of the diagonal width PW22 to the line width PW21 of the openings PRO2 in the non-through region SA is less than a ratio of the diagonal width PW12 to the line width PW11 of the openings PRO2 outside the non-through region SA. For example, in some embodiments, the ratio of the diagonal width PW22 to the line width PW21 of the trench T2 in the non-through region SA is in a range from about 2 to about 2.15, and the ratio of the diagonal width PW12 to the line width PW11 of the openings PRO2 outside the non-through region SA is in a range from about 2.15 to about 2.2. With the configuration, the patterned photoresist layer PR2′ in the non-through region SA is more compact than the patterned photoresist layer PR2′ outside the non-through region SA, which will facilitate the subsequent dual trench process and reduce tiny fence detects. In some embodiments, the diagonal width PW22 of the openings PRO2 in the non-through region SA is less than the diagonal width PW12 of the openings PRO2 outside the non-through region SA. In some other embodiments, the diagonal width PW22 of the openings PRO2 in the non-through region SA can be equal to or greater than the diagonal width PW12 of the openings PRO2 outside the non-through region SA.

In FIG. 8A, the patterned photoresist layer PR2′ may have a first corner RC1 outside the region SA and a second corner RC2 in the region SA in a top view. For achieving the asymmetric profile, the first corner RC1 and the second corner RC2 may have different angles and/or curvature in the top view. For example, an angle of the second corner RC2 is greater than an angle/curvature of the first corner RC1. For example, the second corner RC2 is an obtuse angle, and the first corner RC1 is an acute angle.

Stated differently, in FIGS. 7-8B, a lithography process (e.g., photolithography or e-beam lithography) is performed to form the patterned photoresist layer PR2′ having the openings PRO2. The lithography process includes photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof.

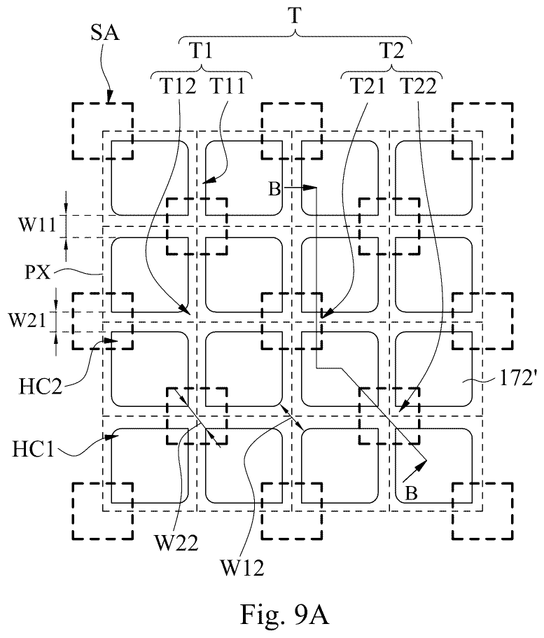

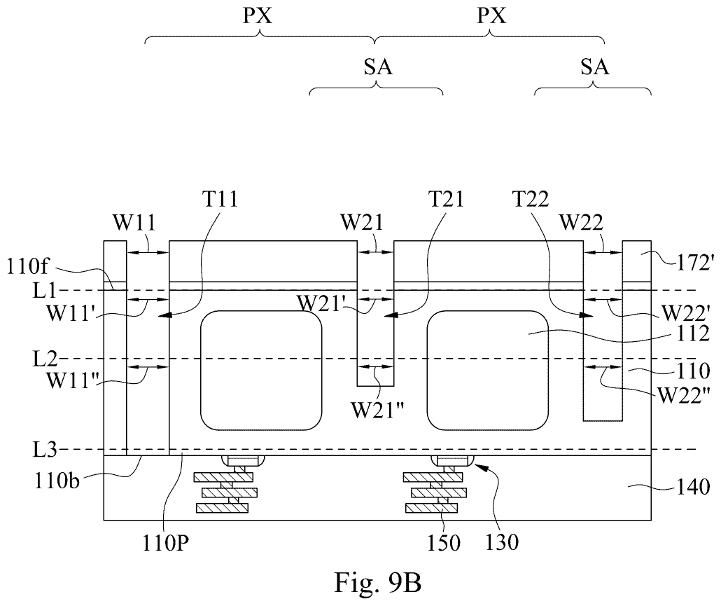

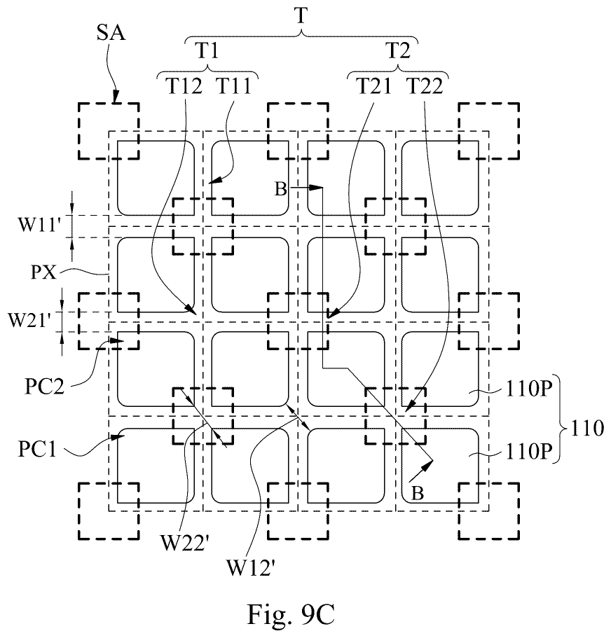

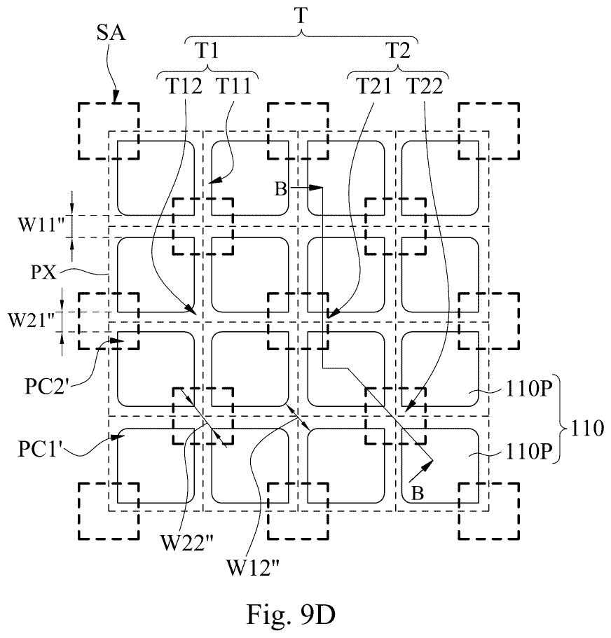

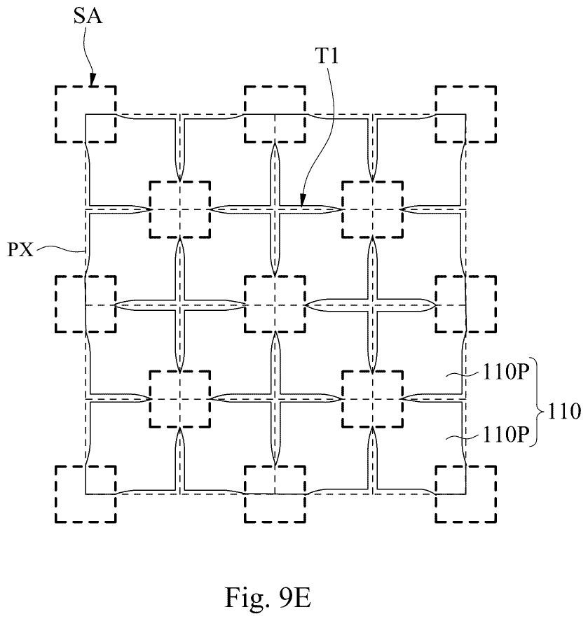

Reference is made to FIGS. 9A-9B. FIG. 9B is a cross-sectional view taken along line B-B of FIG. 9A. An etching process is performed to etch trenches T in the mask layers 180 and 170 and the substrate 110 of FIGS. 8A and 8B. The trenches T may surround plural portions 110P of the substrate 110 corresponding to the pixel regions PX. In some embodiments, each of the portions 110P of the substrate 110 may contain one of the photosensitive regions 112. The etching process may include dry etch, wet etch, or the combination thereof. The etching process is performed by exposing the mask layer 180 (referring to FIGS. 8A and 8B) to one or more etchants with the mask layers 170 and 180 (referring to FIGS. 8A and 8B) in place. The etching process may etch the patterned middle layer 174′ and the middle layer 184 (referring to FIGS. 8A and 8B) at a slower rate than etch the bottom layers 172 and 182 (referring to FIGS. 8A and 8B). Thus, due to the presence of the patterned middle layer 174′ and the middle layer 184 in the non-through regions SA (referring to FIGS. 8A and 8B), the trenches T in the non-through regions SA (denoted as trenches T2) are shallower than the trenches T outside of the non-through regions SA (denoted as trenches T1). For example, bottoms of the trenches T2 are higher than bottoms of the trenches T1. In some embodiments, the etching process can be stopped before the trenches T2 reaches the frontside 110f of the substrate 110, for example, by endpoint detection or by controlling etch time duration. In some embodiments where the endpoint detection is used, the etching process is stopped once the dielectric structure 140 on the frontside 110f of the substrate 110 is exposed by the trench T. The middle layer 184, the bottom layer, and the patterned middle layer 174′ (referring to FIGS. 8A and 8B) may be consumed during the etching process and/or removed by a planarization process after the etching process. For example, the planarization process may include a chemical mechanical polish (CMP) process. After etching the trench T, the bottom layer 172 (referring to FIGS. 8A and 8B) is referred to as a patterned bottom layer 172′, and the trench T extends through the patterned bottom layer 172′ into the substrate 110.

In some embodiments of the present embodiments, the trenches T1 (i.e., the trenches T outside of the non-through regions SA) extend from the backside 110b of the substrate 110 to the frontside 110f of the substrate 110. Thus, the trenches T1 can be referred to as through trenches. Stated differently, the bottoms of the trenches T1 may reach the frontside 110f of the substrate 110, and the trenches T1 may expose the dielectric structure 140 on the frontside 110f of the substrate 110.

In some embodiments, the trenches T1 (i.e., the trenches T outside of the non-through regions SA) may include trenches T11 and trenches T12 connected with the trenches T11. The trenches T11 extend along the directions X and Y between two pixel regions PX. The trenches T12 respectively are located at intersections among four pixel regions PX. In the patterned bottom layer 172′, a diagonal width W12 of the trenches T12 measured along the diagonal direction (e.g., about 45 degrees tilted with respect to the direction X/Y) is greater than a line width W11 of the trenches T11 measured along the direction X/Y. Both the trenches T11 and trenches T12 extend from the backside 110b of the substrate 110 to the frontside 110f of the substrate 110.

In some embodiments of the present embodiments, the trenches T2 (i.e., the trenches T in the non-through regions SA) extend from the backside 110b of the substrate 110 and terminate before reaching the frontside 110f of the substrate 110. Thus, the trenches T2 can be referred to as non-through trenches. For example, bottoms of the trenches T2 are spaced apart from the frontside 110f of the substrate 110 by a portion of the substrate 110.

In some embodiments, the trenches T2 (i.e., the trenches T in the non-through regions SA) may include trenches T21 and trenches T22 connected with the trenches T21. The trenches T21 extend along the directions X and Y between two pixel regions PX. The trenches T22 respectively are located at intersections among four pixel regions PX. In the patterned bottom layer 172′, a diagonal width W22 of the trenches T22 measured along the diagonal direction (e.g., about 45 degrees tilted with respect to the direction X/Y) is greater than a line width W21 of the trenches T21 measured along the direction X/Y. Both the trenches T21 and trenches T22 extend from the backside 110b of the substrate 110 and terminate before reaching the frontside 110f of the substrate 110.

In some embodiments, according to the profile of the patterned photoresist layer PR2′, the trench T result in an asymmetric profile in the patterned bottom layer 172′. For example, the line width W21 of the trenches T21 is greater than the line width W11 of the trenches T11. A difference between the line width W21 and the line width W11 may be in a range from about 3 nm to about 20 nm. If the difference is less than 3 nanometers, the tiny fence detects may not be effectively reduced. If the difference is greater than 20 nanometers, it may be difficult to control the etch loading effect during trench etching process.

In some embodiments, for achieving the asymmetric profile, a ratio of the diagonal width W22 to the line width W21 of the trench T2 is less than a ratio of the diagonal width W12 to the line width W11 of the trench T2. For example, in some embodiments, the ratio of the diagonal width W22 to the line width W21 of the trench T2 is in a range from about 2 to about 2.15, and the ratio of the diagonal width W12 to the line width W11 of the trench T2 is in a range from about 2.15 to about 2.2. With the configuration, the patterned bottom layer 172′ in the non-through region SA is more compact than the patterned bottom layer 172′ outside the non-through region SA. In some embodiments, the diagonal width W22 of the trenches T22 is less than the diagonal width W12 of the trenches T12. In some embodiments, the diagonal width W22 of the trenches T22 can be equal to or greater than the diagonal width W12 of the trenches T12.

In FIG. 9A, the patterned bottom layer 172′ may have a first corner HC1 outside the region SA and a second corner HC2 in the region SA in a top view. For achieving the asymmetric profile, the first corner HC1 and the second corner HC2 may have different angles and/or curvature in the top view. For example, an angle of the second corner HC2 is greater than an angle/curvature of the first corner HC1. For example, the second corner HC2 is an obtuse angle, and the first corner HC is an acute angle.

FIG. 9C is a plan view taken along line L1 of FIG. 9B. FIG. 9D is a plan view taken along line L2 of FIG. 9B. FIG. 9E is a plan view taken along line L3 of FIG. 9B. Reference is made to FIGS. 9B-9E. The trench T is etched downward in the substrate 110, thereby resulting in the width variations at various levels. The trench T may taper downward into the substrate 110 in some embodiments. In some embodiments, by designing the profile of the patterned photoresist layer PR2′ to have an asymmetric profile, the substrate 110 is etched to have an asymmetric profile at an upper level (e.g., the level indicated by the line L1), and an asymmetric profile at a lower level (e.g., the level indicated by the line L2). With the configuration, the trench T can be formed with less the fence defects, thereby reducing the number of the white pixels.

Reference is made to FIGS. 9B and 9C. At the level indicated by the line L1, in the substrate 110, the trenches T11, T12, T21, and T22 of the trench T have widths W11′, W12′, W21′, and W22′, respectively. Like the profile of the patterned bottom layer 172′ (referring to FIG. 9A), the trench T results in an asymmetric profile in the substrate 110. For example, the line width W21′ of the trenches T21 is greater than the line width W11′ of the trenches T11. In some embodiments, a difference between the line width W21′ and width W11′ may be in a range from about 3 nm to about 20 nm. In some embodiments, for achieving the asymmetric profile, a ratio of the diagonal width W22′ to the line width W21′ of the trench T2 is less than a ratio of the diagonal width W12′ to the line width W11′ of the trench T1. For example, in some embodiments, the ratio of the diagonal width W22′ to the line width W21′ of the trench T2 is in a range from about 2 to about 2.15, and the ratio of the diagonal width W12′ to the line width W11′ of the trench T1 is in a range from about 2.15 to about 2.2. In some embodiments, the diagonal width W22′ of the trenches T22 is less than the diagonal width W12′ of the trenches T12. In some other embodiments, the diagonal width W22′ of the trenches T22 is equal to or greater than the diagonal width W12′ of the trenches T12.

In FIG. 9C, the portion 110P of the semiconductor substrate 110 may have a first corner PC1 outside the region SA and a second corner PC2 in the region SA in a top view. For achieving the asymmetric profile, the first corner PC1 and the second corner PC2 may have different angles and/or curvature in the top view. For example, in FIG. 9C, an angle of the second corner PC2 is greater than an angle/curvature of the first corner PC1. For example, in FIG. 9C, the second corner PC2 is an obtuse angle, and the first corner PC is an acute angle.

Reference is made to FIGS. 9B and 9D. At the level indicated by the line L2, in the substrate 110, the trenches T11, T12, T21, and T22 of the trench T have widths W11″, W12″, W21″, and W22″, respectively. In some embodiments, the portions 110P of the substrate 110 surrounded by the trench T at the level indicated by the line L2 shows a different asymmetric profile with respect to the portions 110P of the substrate 110 surrounded by trench T at the level indicated by the line L1. For example, the line width W21″ of the trenches T21 is less than the line width W11″ of the trenches T11. In some embodiments, the diagonal width W22″ of the trenches T22 is different from (e.g., greater or less than) the diagonal width W12″ of the trenches T12. In some embodiments, the diagonal width W22″ of the trenches T22 is greater or less than the diagonal width W12″ of the trenches T12. In some embodiments, owing to the taper profile of the trench T, the widths W11″, W12″, W21″, and W22″ may be respectively less than the widths W11′, W12′, W21′, and W22′ in FIG. 9C.

In FIG. 9D, the portion 110P of the semiconductor substrate 110 may have a first corner PC1′ outside the region SA and a second corner PC2′ in the region SA in a top view. For achieving the asymmetric profile, the first corner PC1′ and the second corner PC2′ may have different angles and/or curvature in the top view.

Reference is made to FIGS. 9B and 9E. At the level indicated by the line L3, the non-through region SA is free of the trenches T2, and only the trenches T1 is left in the substrate 110.

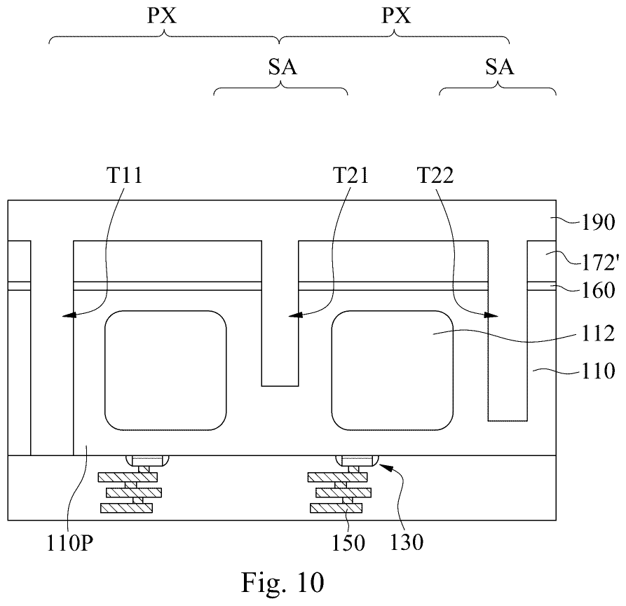

Reference is made to FIG. 10. The trench T including trenches T1 and T2 (referring to FIGS. 9A-9E) is overfilled with a dielectric material 190. In various embodiments, the dielectric material 190 may include an oxide, such as silicon oxide, TEOS, etc. Any suitable deposition technique, such as chemical vapor deposition (CVD), can be used to form the dielectric material 190.

Reference is made to FIGS. 11A-11B. FIG. 11B is a cross-sectional view taken along line B-B of FIG. 11A. After overfilling the trench T with the dielectric material 190, a planarization process such as CMP is then performed to remove a portion of the dielectric material 190 out of the trench T. Remaining portions of the dielectric material 190 in the trench T is referred to as an isolation feature 190′. In some embodiments, the isolation feature 190′ may be referred to as DTI structures. The isolation feature 190′ may include through isolation features 192 and non-through isolation features 194 in the trenches T1 and T2 (referring to FIG. 9C), respectively.

FIG. 11A can be consider as a plan view taken along line L1 of FIG. 11B. FIG. 11C is a plan view taken along line L2 of FIG. 11B. FIG. 11D is a plan view taken along line L3 of FIG. 11B. The isolation feature 190′ tapers downward in the substrate 110, thereby resulting in the width variations at various levels.

Reference is made to FIGS. 11A and 11B. Following the pattern and profile of the trench T in FIG. 9C, the through isolation features 192 have a line width A11′ and a diagonal width A12′ corresponding the line width W11′ and the diagonal width W12′ of the trench T1, and the non-through isolation features 194 have a line width A21′ and a diagonal width A22′ corresponding the line width W21′ and the diagonal width W22′ of the trench T2, respectively. At the level indicated by the line L1, the isolation feature 190′ results in an asymmetric profile in the substrate 110. For example, the line width A21′ of the non-through isolation features 194 is greater than the line width A11′ of the through isolation features 192. For example, a difference between the line width A21′ and the line width A11′ is in a range from about 3 nm to about 20 nm. With the configuration, a ratio of the diagonal width A22′ to the line width A21′ of the non-through isolation features 194 is less than a ratio of the diagonal width A12′ to the line width A11′ of the through isolation features 192. For example, in some embodiments, the ratio of the diagonal width A22′ to the line width A21′ of the non-through isolation features 194 is in a range from about 2 to about 2.15, and the ratio of the diagonal width A12′ to the line width A11′ of the through isolation features 192 is in a range from about 2.15 to about 2.2.

In some embodiments, the diagonal width A22′ of the non-through isolation features 194 is less than the diagonal width A12′ of the through isolation features 192. In some other embodiments, the diagonal width A22′ of the non-through isolation features 194 is equal to or greater than the diagonal width A12′ of the through isolation features 192.

Reference is made to FIGS. 11B and 11C. Following the pattern and profile of the trench T in FIG. 9D, the through isolation features 192 have a line width A11″ and a diagonal width A12″ corresponding the line width W11″ and the diagonal width W12″ of the trench T1, and the non-through isolation features 194 have a line width A21″ and a diagonal width A22″ corresponding the line width W21″ and the diagonal width W22″ of the trench T2, respectively. The portion 110P of the substrate 110 surrounded by the isolation features 190′ at the level indicated by the line L2 shows a different asymmetric profile than the portion 110P of the substrate 110 surrounded by the isolation features 190′ at the level indicated by the line L1. For example, the line width A21″ of the through isolation features 194 is less than the line width A11″ of the through isolation features 192. In some embodiments, the diagonal width A22″ of the non-through isolation features 194 is different from (e.g., greater or less than) the diagonal width A12″ of the through isolation features 192. In some embodiments, owing to the taper profile of the isolation features 190′, the widths A11″, A12″, A21″, and A22″ are respectively less than the widths A11′, A12′, A21′, and A22′ in FIG. 11A.

Reference is made to FIGS. 11B and 11D. At the level indicated by the line L3, the non-through region SA is free of the non-through isolation features 194, and only the through isolation features 192 is left in the substrate 110.

In the context, the widths PW11, PW12, PW21, and PW22 of the patterned photoresist layer PR2′, the widths W11, W12, W21, W22, W11′, W12′, W21′, W22′, W11″, W12″, W21″, and W22″ of the trenches T, and the widths A11′, A12′, A21′, A 22′ A11″, A12″, A21″, and A22″ of the isolation features 190′ may not be drawn to scale.

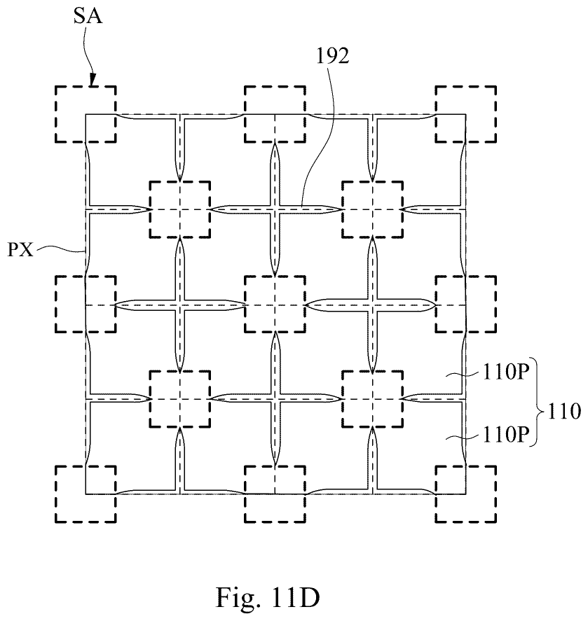

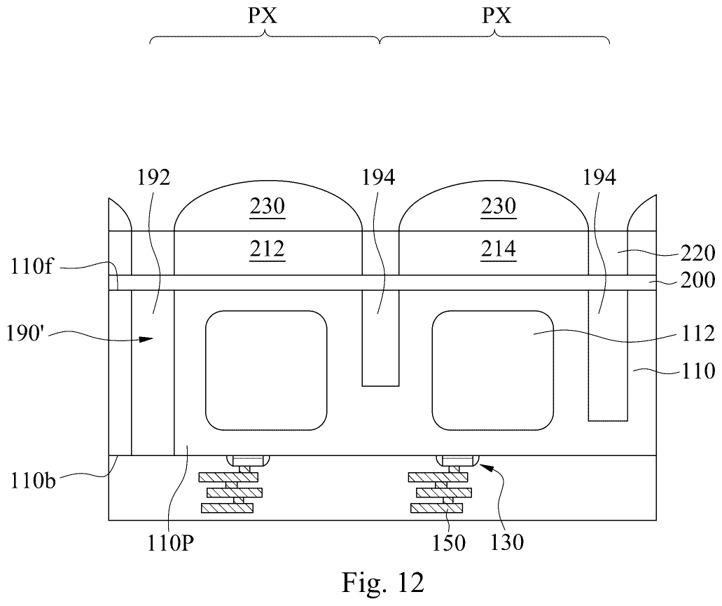

Reference is made to FIG. 12. A dielectric planarization structure 200 is formed over the isolation features 192 and 194 and the substrate 110, and then plural color filters 212 and 214 are formed over the dielectric planarization structure 200. In some embodiments, the color filters 212 and 214 may be formed within openings in a grid structure 220 overlying the dielectric planarization structure 200. In some embodiments, plural color filters 212 and 214 may be formed by forming a color filter layer and patterning the color filter layer. The color filter layer is formed of a material that allows for the transmission of radiation (e.g., light) having a specific range of wavelength, while blocking light of wavelengths outside of the specified range. Plural micro-lenses 230 are formed over the color filters 212 and 214 for collecting photons into pixels. The grid structure 220 may be positioned between adjacent color filters to prevent cross contamination of photons in adjacent pixels. The impinging photons are therefore entering the image sensing device through the backside 110b. At the presence of high aspect ratio DTI features 190′, the photons entering one of the photosensitive regions 112 are barred from travelling to the adjacent photosensitive regions 112, and thus cross contamination of the incoming signal can be reduced.

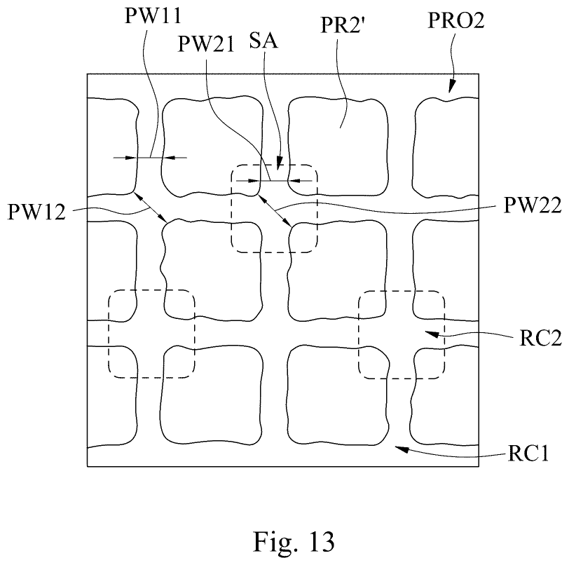

FIG. 13 is a top view of a patterned photoresist layer PR2′ according to various embodiments of the present disclosure. Like the patterned photoresist layer PR2′ in FIG. 8A, the patterned photoresist layer PR2′ has plural openings PRO2, which separates the pixel regions from each other. As aforementioned, the patterned photoresist layer PR2′ has an asymmetric profile. For example, the line width PW21 of the openings PRO2 in the non-through region SA is greater than the line width PW11 of the openings PRO2 outside the non-through region SA. And, for achieving the asymmetric profile, a ratio of the diagonal width PW22 to the line width PW21 of the openings PRO2 in the non-through region SA is less than a ratio of the diagonal width PW12 to the line width PW11 of the openings PRO2 outside the non-through region SA. In some embodiments, the diagonal width PW22 of the openings PRO2 in the non-through region SA can be less than, equal to, or greater than the diagonal width PW12 of the openings PRO2 outside the non-through region SA.

The patterned photoresist layer PR2′ may have a first corner RC1 outside the region SA and a second corner RC2 in the region SA in a top view. For achieving the asymmetric profile, the first corner RC1 and the second corner RC2 may have different angles and/or curvature in the top view. For example, an angle of the second corner RC2 is greater than an angle/curvature of the first corner RC1. Other details of the patterned photoresist layer PR2′ are similar to those illustrated in FIG. 8A, and therefore not repeated herein.

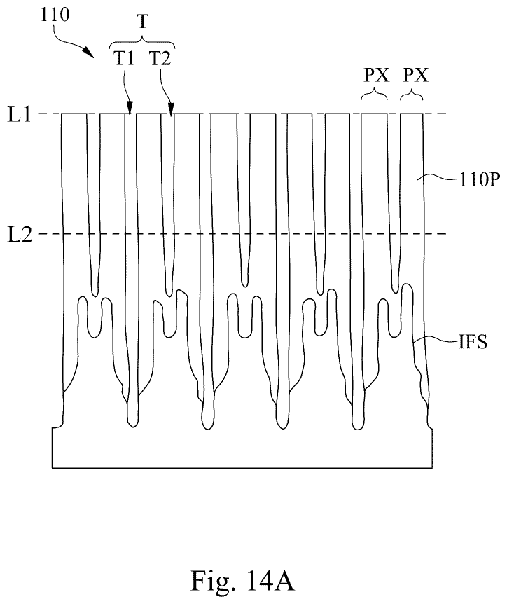

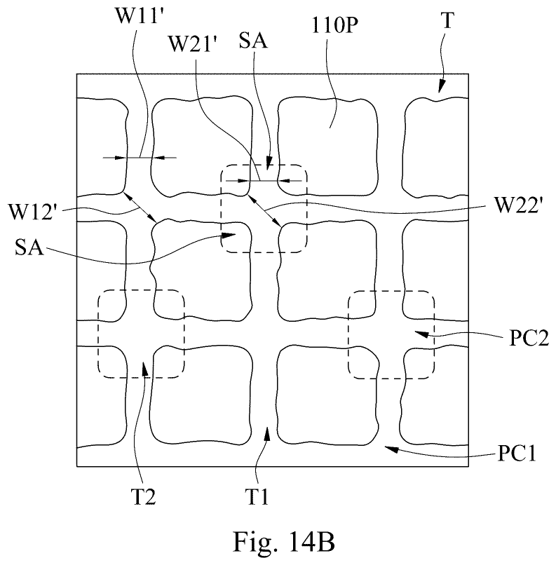

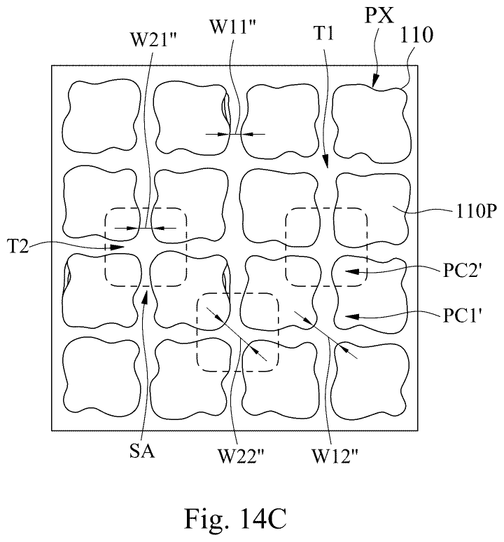

FIG. 14A is a cross-sectional view of an image sensor device according to various embodiments of the present disclosure. FIG. 14B is a top view of the image sensor device of FIG. 14A, for example, a plan view taken along the line L1 of FIG. 14A. FIG. 14C is a plan view of the image sensor device of FIG. 14A, for example, taken along the line L2 of FIG. 14A. FIGS. 14A-14C shows the image sensor device as illustrated in FIGS. 9B-9D. The trenches T are etched in the substrate 110 to surround plural portions 110P of the substrate 110 corresponding to the pixel regions PX. The trenches T in the non-through regions SA (denoted as trenches T2) are shallower than the trenches T outside of the non-through regions SA (denoted as trenches T1). For example, bottoms of the trenches T2 are higher than bottoms of the trenches T1.

In FIG. 14A, by etching the trench T in the substrate 110, a semiconductor interface IFS may be inherently formed in the substrate 110. In the present embodiments, by etching the trench T in the substrate 110, a semiconductor interface IFS may be inherently formed in the substrate 110. The semiconductor interface IFS may space a first portion of the semiconductor substrate 110 from a second portion of the semiconductor substrate 110, in which the first and second portions of the semiconductor substrate 110 includes the same semiconductor material, such as silicon. In some cases where the trench T is not etched with the designed asymmetric pattern, the semiconductor interface IFS may show fence defects, which may increase the number of the white pixels. In some embodiments of the present disclosure, by etching the trench T with the designed asymmetric pattern, the fence defects in the semiconductor interface IFS may be reduced or eliminated, thereby reducing the number of the white pixels.

In FIG. 14B, the trench T results in an asymmetric profile in the substrate 110. For example, the line width W21′ of the trench T2 in the non-through region SA is greater than the line width W11′ of the trenches T1 outside the non-through region SA. In some embodiments, for achieving the asymmetric profile, a ratio of the diagonal width W22′ to the line width W21′ of the trench T2 is less than a ratio of the diagonal width W12′ to the line width W11′ of the trench T1. In some embodiments, the diagonal width W22′ of the trenches T22 can be less than, equal to, or greater than the diagonal width W12′ of the trenches T12.

In FIG. 14B, the portion 110P of the semiconductor substrate 110 may have a first corner PC1 outside the region SA and a second corner PC2 in the region SA in a top view. For achieving the asymmetric profile, the first corner PC1 and the second corner PC2 may have different angles and/or curvature in the top view. For example, in FIG. 14B, an angle of the second corner PC2 is greater than an angle/curvature of the first corner PC1.

In FIG. 14C, the trench T results in an asymmetric profile in the substrate 110. For example, the line width W21″ of the trench T2 in the non-through region SA is less than the line width W11″ of the trenches T1 outside the non-through region SA. In some embodiments, the diagonal width W22′ of the trenches T22 can be less than, equal to, or greater than the diagonal width W12′ of the trenches T12.

In FIG. 14C, the portion 110P of the semiconductor substrate 110 may have a first corner PC1′ outside the region SA and a second corner PC2′ in the region SA in a top view. For achieving the asymmetric profile, the first corner PC1′ and the second corner PC2′ may have different angles and/or curvature in the top view. Other details of the present embodiments are similar to those illustrated in the embodiments of FIGS. 1-12, and thereto not repeated herein.

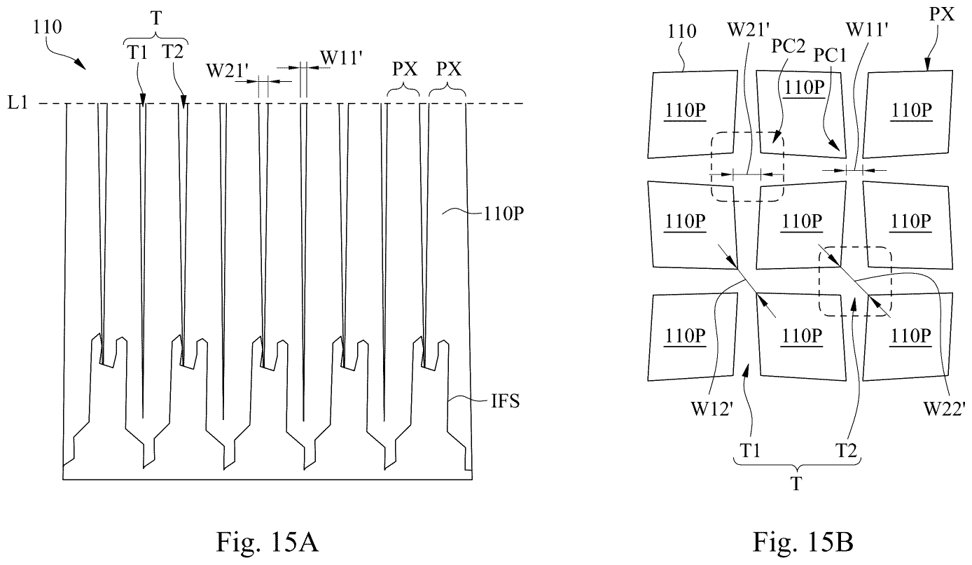

FIG. 15A is a cross-sectional view of an image sensor device according to various embodiments of the present disclosure. FIG. 15B is a top view of the image sensor device of FIG. 15A, for example, a plan view taken along the line L1 of FIG. 15A. FIGS. 15A-15B shows the image sensor device as illustrated in FIGS. 9B and 9C. In the present embodiments, the trench T including trenches T1 and T2 is etched in the substrate 110 such that the trench T1 is deeper than the trench T2. In FIG. 15B, the trench T results in an asymmetric profile in the substrate 110. For example, the line width W21′ of the trench T2 in the non-through region SA is greater than the line width W11′ of the trenches T1 outside the non-through region SA. In some embodiments, for achieving the asymmetric profile, a ratio of the diagonal width W22′ to the line width W21′ of the trench T2 is less than a ratio of the diagonal width W12′ to the line width W11′ of the trench T1. In some embodiments, the diagonal width W22′ of the trenches T22 can be less than, equal to, or greater than the diagonal width W12′ of the trenches T12.

In FIG. 15B, the portion 110P of the semiconductor substrate 110 may have a first corner PC1 outside the region SA and a second corner PC2 in the region SA in a top view. For achieving the asymmetric profile, the first corner PC1 and the second corner PC2 may have different angles and/or curvature in the top view. For example, in FIG. 14B, an angle of the second corner PC2 is greater than an angle/curvature of the first corner PC1. For example, in FIG. 15B, the second corner PC2 is an obtuse angle, and the first corner PC is an acute angle. As aforementioned, by etching the trench T in the substrate 110, a semiconductor interface IFS may be inherently formed in the substrate 110. Other details of the present embodiments are similar to those illustrated in the embodiments of FIGS. 1-12, and thereto not repeated herein.

Based on the above discussions, it can be seen that the present disclosure offers advantages. It is understood, however, that other embodiments may offer additional advantages, and not all advantages are necessarily disclosed herein, and that no particular advantage is required for all embodiments. One of the advantages is that by etching dual trenches at a backside of the semiconductor substate with a designed asymmetric pattern, the fence defects in the semiconductor interface may be reduced or eliminated, thereby reducing the number of the white pixels.

In some embodiments of the present disclosure, a method for fabricating an image sensor device is provided. The method includes forming a plurality of photosensitive regions in a semiconductor substrate through a frontside of the semiconductor substrate; etching a first trench and a second trench in a backside of the semiconductor substrate after forming the photosensitive regions, wherein the first trench is deeper than the second trench, and a first line width of the first trench is less than a second line width of the second trench in a first top view; and forming a first isolation feature in the first trench and a second isolation feature in the second trench.

In some embodiments of the present disclosure, a method for fabricating an image sensor device is provided. The method includes forming a photosensitive region in a portion of a semiconductor substrate; etching a trench in a backside of the semiconductor substrate after forming the photosensitive region, wherein the trench surrounds the portion of the semiconductor substrate, the portion of the semiconductor substrate has a first corner and a second corner in a top view, and an angle of the first corner is less than an angle of the second corner in the top view; and forming an isolation feature in the trench.

In some embodiments of the present disclosure, an image sensor device includes a semiconductor substrate, photosensitive regions, an interconnect layer, and an isolation feature. The photosensitive regions are respectively in a plurality of portions of the semiconductor substrate. The interconnect layer is on a frontside of the semiconductor substrate. The isolation feature extends from the backside of the semiconductor substrate toward the frontside of the semiconductor substrate and surrounding the portions of the semiconductor substrate, wherein the isolation feature has a first isolation feature and a second isolation feature, the first isolation feature has a bottom lower than that of the second isolation feature, and a first line width of the first isolation feature is less than a second line width of the second isolation feature in a top view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating an image sensor device, comprising:
forming a plurality of photosensitive regions in a semiconductor substrate through a frontside of the semiconductor substrate;
etching a first trench and a second trench in a backside of the semiconductor substrate after forming the photosensitive regions, wherein the first trench is deeper than the second trench, and a first line width of the first trench is less than a second line width of the second trench in a first top view; and
forming a first isolation feature in the first trench and a second isolation feature in the second trench.

2. The method of claim 1, wherein etching the first and second trenches is performed such that a ratio of a second diagonal width to the second line width of the second trench is less than a ratio of a first diagonal width to the first line width of the first trench.

3. The method of claim 1, wherein etching the first and second trenches is performed such that a first diagonal width of the first trench is different from a second diagonal width of the second trench in the first top view.

4. The method of claim 1, wherein etching the first and second trenches is performed such that a first diagonal width of the first trench is greater than a second diagonal width of the second trench in the first top view.

5. The method of claim 1, further comprising:
forming a first patterned mask layer exposing a first region and covering a second region; and
forming a second mask layer over the first patterned mask layer, wherein etching the first trench and the second trench is performed with the first patterned mask layer and the second mask layer in place, and the first trench is in the first region, and the second trench is in the second region.

6. The method of claim 1, further comprising:
prior to etching the first and second trenches, forming a photoresist layer over the backside of the semiconductor substrate, wherein the photoresist layer has a first opening and a second opening, and a line width of the first opening is less than a line width of the second opening in a second top view.

7. The method of claim 1, further comprising:
forming an interconnect layer on the frontside of the semiconductor substrate after forming the photosensitive regions.

8. The method of claim 7, wherein etching the first and second trenches is performed such that the first trench exposes a dielectric structure surrounding the interconnect layer.

9. A method for fabricating an image sensor device, comprising:
forming a photosensitive region in a portion of a semiconductor substrate;
etching a trench in a backside of the semiconductor substrate after forming the photosensitive region, wherein the trench surrounds the portion of the semiconductor substrate, the portion of the semiconductor substrate has a first corner and a second corner in a top view, and an angle of the first corner is less than an angle of the second corner in the top view; and
forming an isolation feature in the trench.

10. The method of claim 9, wherein the angle of the first corner is an acute angle.

11. The method of claim 9, wherein the angle of the second corner is an obtuse angle.

12. The method of claim 9, wherein etching the trench is performed such that the trench has a first depth surrounding the first corner of the portion of the semiconductor substrate and a second depth surrounding the second corner of the portion of the semiconductor substrate, and the first depth is less than the second depth.

13. The method of claim 9, wherein forming the isolation feature is performed such that the isolation feature surrounds the first corner and the second corner of the portion of the semiconductor substrate.

14. The method of claim 9, further comprising:
before etching the trench and after forming the photosensitive region, forming an interconnect layer on a frontside of the semiconductor substrate.

15. An image sensor device, comprising:
a semiconductor substrate;
a plurality of photosensitive regions respectively in a plurality of portions of the semiconductor substrate
an interconnect layer on a frontside of the semiconductor substrate; and
an isolation feature extending from a backside of the semiconductor substrate toward the frontside of the semiconductor substrate and surrounding the portions of the semiconductor substrate, wherein the isolation feature has a first isolation feature and a second isolation feature, the first isolation feature has a bottom lower than that of the second isolation feature, and a first line width of the first isolation feature is less than a second line width of the second isolation feature in a top view.

16. The image sensor device of claim 15, wherein a first diagonal width of the first isolation feature is different from a second diagonal width of the second isolation feature in the top view.

17. The image sensor device of claim 15, wherein a ratio of a second diagonal width to the second line width of the second isolation feature is less than a ratio of a first diagonal width to the first line width of the first isolation feature.

18. The image sensor device of claim 15, wherein the first isolation feature extends through the semiconductor substrate.

19. The image sensor device of claim 15, further comprising:
a dielectric structure surrounding the interconnect layer, where the first isolation feature is in contact with the dielectric structure.

20. The image sensor device of claim 19, wherein the second isolation feature is spaced apart from the dielectric structure.
